(19) United States
(12) Patent Application Publication
(10) Pub. No.: US 2007/0241425 A1
(43) Pub. Date: Oct. 18, 2007

(54) THREE-DIMENSIONAL CAPACITOR STRUCTURE

(76) Inventor: Chien-Chia Lin, Kao-Hsiung City (TW)

Correspondence Address: NORTH AMERICA INTELLECTUAL PROPERTY CORPORATION, P.O. BOX 506, MERRIFIELD, VA, 22116, US

(21) Appl. No.: 11/468,293

(22) Filed: Aug. 29, 2006

(30) Foreign Application Priority Data
Apr. 13, 2006 (TW) 095113199

(51) Int. Cl. H01L 29/00

(52) U.S. Cl. 257/532

(57) ABSTRACT

A three-dimensional capacitor structure has a first conductive layer, a second conductive layer disposed above the first conductive layer, and a plug layer disposed between the conductive layers. The first conductive layer includes first conductive closed-end frames, and first conductive islands disposed inside the first conductive closed-end frames. The second conductive layer includes second conductive closed-end frames, and second conductive islands disposed inside the second conductive closed-end frames. The second conductive closed-end frames line up with the first conductive islands, and the second conductive islands line up with the first conductive closed-end frames. The plug layer has plugs disposed in between each first conductive island and each second conductive closed-end frame, and in between each first conductive closed-end frame and each second conductive island.

### BACKGROUND OF THE INVENTION

1. Field of the Invention

The present invention relates to a capacitor structure, and more particularly, to a three-dimensional capacitor structure having low resistance and high matching.

2. Description of the Prior Art

Capacitor structures are able to store charges, and can be applied in many sorts of integrated circuits, such as RFICs and MMICs. A capacitor structure consists of two parallel electrical plates with an insulation layer between the plates. Please refer to FIG. 1. FIG. 1 is a schematic diagram of a metal-insulator-metal (MIM) capacitor structure according to the prior art. As FIG. 1 shows, the MIM capacitor structure 10 comprises a substrate 12, a first electrical plate 14 disposed on the substrate 12, a capacitor dielectric layer 16 located on the first electrical plate 14, and a second electrical plate 18 disposed on the capacitor dielectric layer 16.

An inter-digitated capacitor structure has been gradually replacing the conventional MIM capacitor structure. U.S. Pat. No. 5,583,359 discloses an inter-digitated capacitor structure. Please refer to FIGS. 2-3. FIG. 2 is a perspective view of a prior art inter-digitated capacitor structure 30. FIG. 3 is a sectional view of the prior art inter-digitated capacitor structure 30, taken across a section III-III of FIG. 2. As FIGS. 2-3 show, the prior art inter-digitated capacitor structure 30 comprises a first electrode structure and a second electrode structure. The first electrode structure comprises a plurality of first metal patterns 32 stacked vertically with respect to each other. The second electrode structure comprises a plurality of second metal patterns 34 stacked vertically with respect to each other. In addition, each first metal pattern 32 comprises a first peripheral part 321 and a plurality of first finger parts 322 connected to the first peripheral part 321. Each second metal pattern 34 comprises a second peripheral part 341 and a plurality of second finger parts 342 connected to the second peripheral part 341. Furthermore, a capacitor dielectric layer 38 (not shown in FIG. 2) is disposed between each first metal pattern 32 and each second metal pattern 34. The prior art inter-digitated capacitor structure 30 further comprises a plurality of first connective plugs 40 disposed among the capacitor dielectric layers 38 between the first peripheral parts 321 of each first metal pattern 32, so every first metal pattern 32 is mutually electrically connected. Additionally, a plurality of second connective plugs 42 is disposed among the capacitor dielectric layer 38 between the second peripheral parts 341 of each second metal pattern 34, so every second metal pattern 34 is mutually electrically connected.

As FIG. 2 shows, the first metal patterns 32 connected with each other by the first connective plugs 40 make up a first electrode structure. The second metal patterns 34 connected with each other by the second connective plugs 42 make up a second electrode structure. Furthermore, the first metal patterns 32, the second metal patterns 34, and the capacitor dielectric layer 38 between the first metal patterns 32 and the second metal patterns 34 form the prior art inter-digitated capacitor structure 30. As FIG. 3 shows, the first finger parts 322 of the first metal patterns 32 are connected to a positive voltage, and the second finger parts 342 of the second metal patterns 34 are connected to a negative voltage.

The prior art teaches another embodiment of the inter-digitated capacitor structure. Please refer to FIGS. 4-5. FIG. 4 is a perspective view of a prior art inter-digitated capacitor structure 50. FIG. 5 is a sectional view of the prior art inter-digitated capacitor structure 50, taken across a section V-V of FIG. 4. As FIGS. 4-5 show, the prior art inter-digitated capacitor structure 50 comprises a first electrode structure and a second electrode structure. The first electrode structure comprises a plurality of first metal patterns 52 stacked vertically with respect to each other. The second electrode structure comprises a plurality of second metal patterns 54 stacked vertically with respect to each other. In addition, each first metal pattern 52 comprises a first peripheral part 521 and a plurality of first finger parts 522 connected with the first peripheral part 521. Each second metal pattern 54 comprises a second peripheral part 541 and a plurality of second finger parts 542 connected with the second peripheral part 541. Furthermore, between each first metal pattern 52 and each second metal pattern 54, a capacitor dielectric layer 58 (not shown in FIG. 4) is disposed. The prior art inter-digitated capacitor structure 50 further comprises a plurality of first connective plugs 60 disposed among the capacitor dielectric layers 58 between the first peripheral parts 521 of each first metal pattern 52, so every first metal pattern 52 is mutually electrically connected. Additionally a plurality of second connective plugs 62 are disposed among the capacitor dielectric layers 58 between the second peripheral parts 541 of each second metal pattern 54, so every second metal pattern 54 is mutually electrically connected.

As FIGS. 4-5 show, the difference between the inter-digitated capacitor structure of FIGS. 2-3 and the inter-digitated capacitor structure of FIGS. 4-5 is that the first electrode structure of the inter-digitated capacitor structure 50 is mismatched with the second electrode structure. Therefore, a first finger part 522 forms four capacitors with four second finger parts 542, respectively, that are adjacent to the first finger part 522.

Compared with the MIM capacitor structure, the inter-digitated capacitor structure shows improved capacitance while maintaining the same size. The capacitance, however, is not the only consideration in the design of the capacitor structure. Because the fingers of the inter-digitated capacitor structure have longer lengths, and the fingers are only connected electrically on one side, the resistance is correspondingly high, and the matching of the inter-digitated capacitor structure needs to be improved.

### SUMMARY OF THE INVENTION

One purpose of the present invention is providing a three-dimensional capacitor structure with low resistance and high matching.

To accomplish the above-mentioned purpose, the present invention provides a three-dimensional capacitor structure comprising a first conductive layer, a second conductive layer disposed on the first conductive layer, and a plug layer between the first conductive layer and the second conductive layer. The first conductive layer comprises a plurality of first closed conductive frames disposed in a matrix, and a plurality of first conductive islands individually disposed in the first closed conductive frames. The first conductive islands are not electrically connected to the first closed conductive frames. The above-mentioned second conductive layer comprises a plurality of second closed conductive frames disposed in a matrix, and a plurality of second conductive islands individually disposed in the second closed conductive frames. The second conductive islands are not connected electrically with the second closed conductive frames. The second closed conductive frames of the second conductive layer correspond to the first conductive islands of the first conductive layer. The second conductive islands of the second conductive layer correspond to the first closed conductive frames of the first conductive layer. The above-mentioned plug layer comprises a plurality of plugs. Each plug is between each first conductive island and each second closed conductive frame, and between each first closed conductive frame and each second conductive island.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a metal-insulator-metal (MIM) capacitor structure according to the prior art.

FIG. 2 is a perspective view of a prior art inter-digitated capacitor structure.

FIG. 3 is a sectional view of the prior art inter-digitated capacitor structure, taken across a section III-III of FIG. 2.

FIG. 4 is a perspective view of a prior art inter-digitated capacitor structure.

FIG. 5 is a sectional view of the prior art inter-digitated capacitor structure, taken across a section V-V of FIG. 4.

FIGS. 6-8 are layout diagrams of a three-dimensional capacitor structure of an embodiment according to the present invention.

FIG. 9 is a perspective view of a three-dimensional capacitor structure of an embodiment according to the present invention.

FIG. 10 is a cross-sectional diagram of the three-dimensional capacitor structure in FIG. 9 along a section A-A′.

FIG. 11 is a cross-sectional diagram of the three-dimensional capacitor structure in FIG. 9 along a section B-B′.

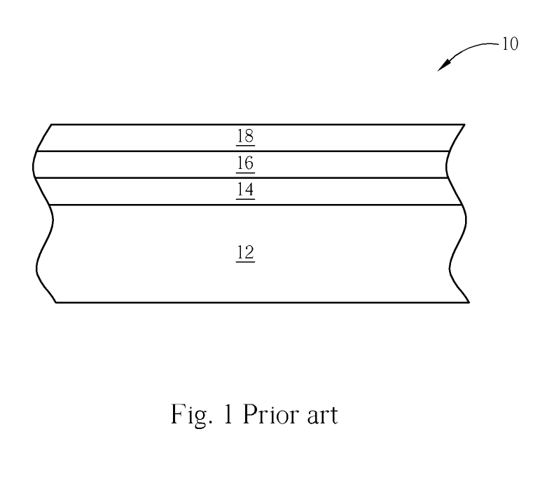

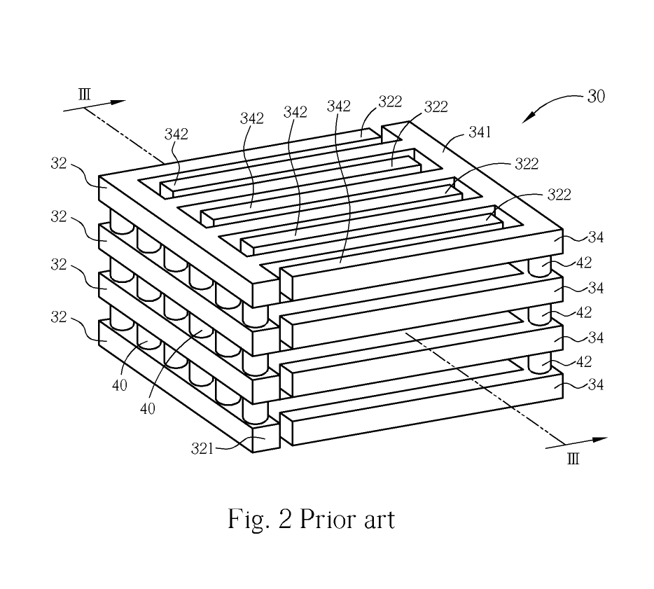

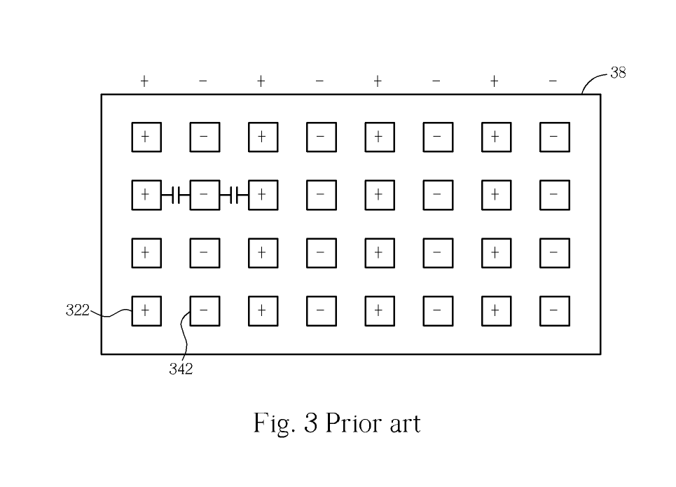

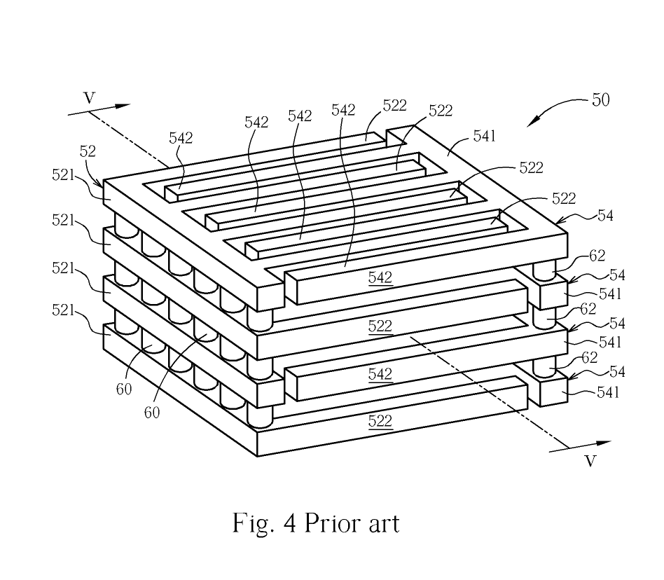

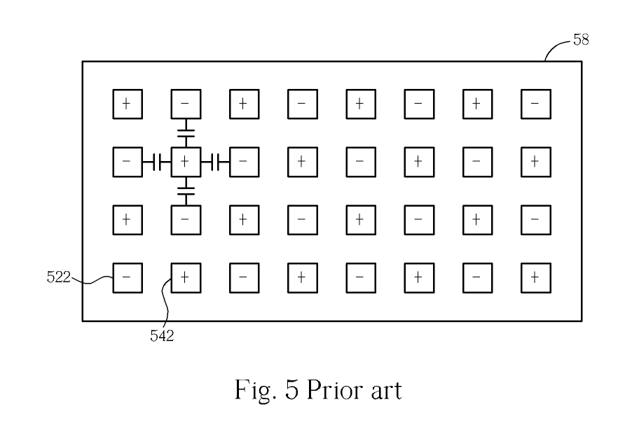

### DETAILED DESCRIPTION

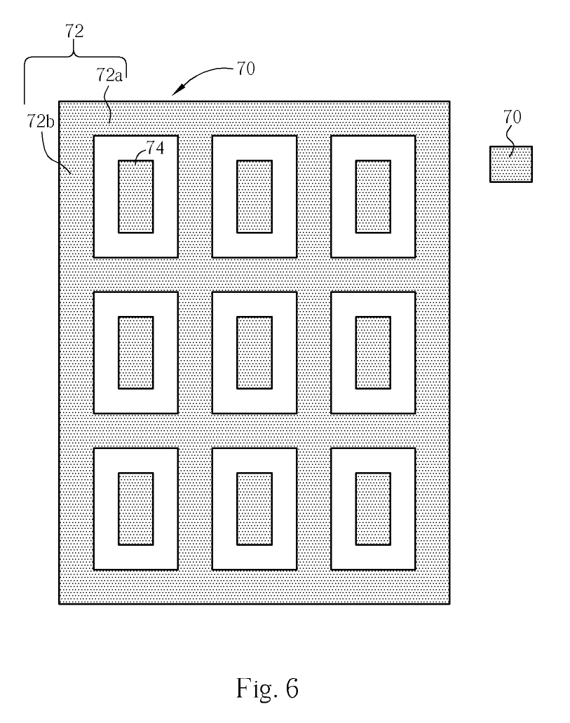

Please refer to FIGS. 6-8. FIGS. 6-8 are layout diagrams of a three-dimensional capacitor structure of an embodiment according to the present invention. As FIG. 6 shows, the three-dimensional capacitor structure comprises a first conductive layer 70, which comprises a plurality of first closed conductive frames 72 in a matrix, and a plurality of conductive islands 74 disposed individually in the first closed conductive frames 72. The first conductive island 74 does not connect electrically with the first closed conductive frame 72. In this embodiment, the first closed conductive frames 72 are rectangles, and connect with each other in a matrix. In addition, each first closed conductive frame 72 comprises two conductive strips 72a along a first direction (horizontal in the diagram), and two conductive strips 72b along a second direction (vertical in the diagram).

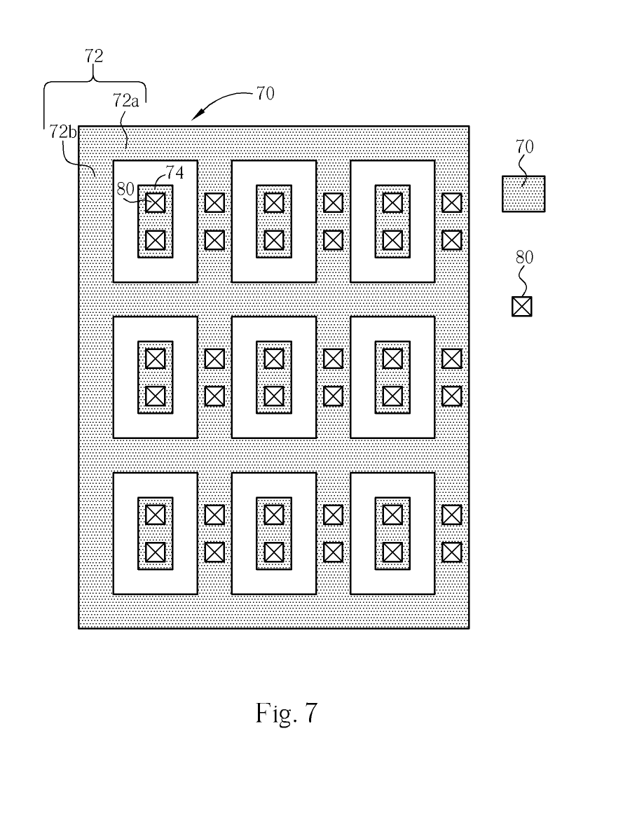

As FIG. 7 shows, the three-dimensional capacitor structure comprises a plug layer on the first conductive layer 70. The plug layer comprises a plurality of plugs 80. The plugs 80 correspond to the conductive strip 72a of the first closed conductive frame 72 along the first direction, and the first conductive island 74.

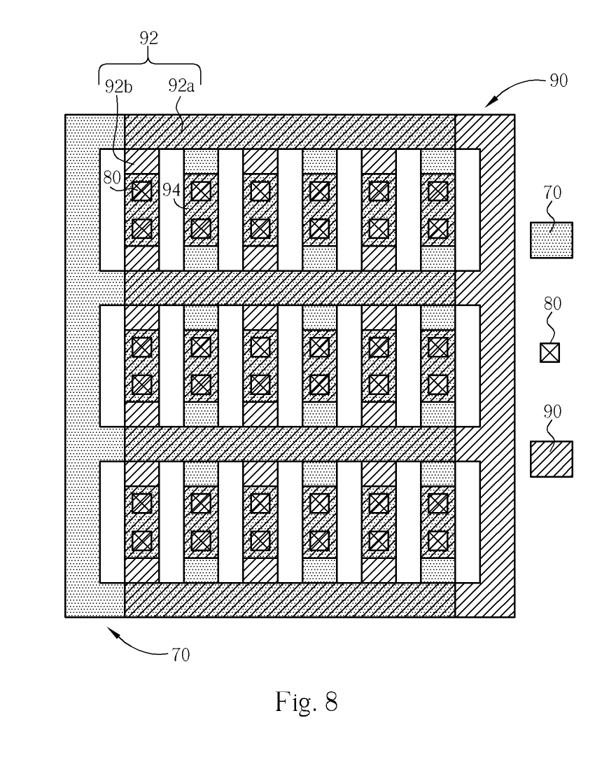

As FIG. 8 shows, the three-dimensional capacitor structure comprises a second conductive layer 90 disposed on the plug layer. The second conductive layer 90 comprises a plurality of second closed conductive frames 92 in a matrix, and a plurality of second conductive islands 94 individually disposed in the second closed conductive frames 92. The second conductive island 94 does not connect with the second closed conductive frame 92. In this embodiment, the second closed conductive frames 92 are rectangles. Each second closed conductive frame 92 comprises two conductive strips 92a along a first direction, and two conductive strips 92b along a second direction.

In this embodiment, the second conductive layer 90 and the first conductive layer 70 have a similar layout. A difference is that the second conductive layer 90 and the first conductive layer 70 are placed at an offset. In other words, the position of the second conductive layer 90 is offset from the position of the first conductive layer 70 along the second direction, so that the conductive strip 92a of the second conductive closed frame 92 of the second conductive layer 90 corresponds to the first conductive island 74 of the first conductive layer 70, and the conductive strip 92a connects electrically by the plug 80 to the first conductive island 74. The second conductive island 94 of the second conductive layer 90 corresponds to the conductive strips 72a of the first closed frame 72 of the first conductive layer 70, and they connect electrically through the plug 80 between them.

In the above-mentioned embodiment of the present invention, the first conductive layer 70 and the second conductive layer 90 both have a symmetrical layout, so the three-dimensional capacitor structure of the present invention has high matching. The first closed conductive frame 72 and the second closed conductive frame 92 connect with each other in a matrix, which lowers resistance.

The above-mentioned first conductive layer 70, the plug layer, and the second conductive layer 90 are foundational units of the three-dimensional capacitor structure of the present invention. The first conductive layer 70 and the second conductive layer 90 are connected to different voltages, such that one conductive layer connects to a positive voltage, and the other conductive layer connects to a negative voltage. In practice, the three-dimensional capacitor structure of the present invention is not limited to the three-layered stacked structure. The structure could be changed that depends on the capacitance or the amount of the multilevel interconnects. For example, the three-dimensional capacitor structure of the present invention could be extended to five conductive layers and four plug layers.

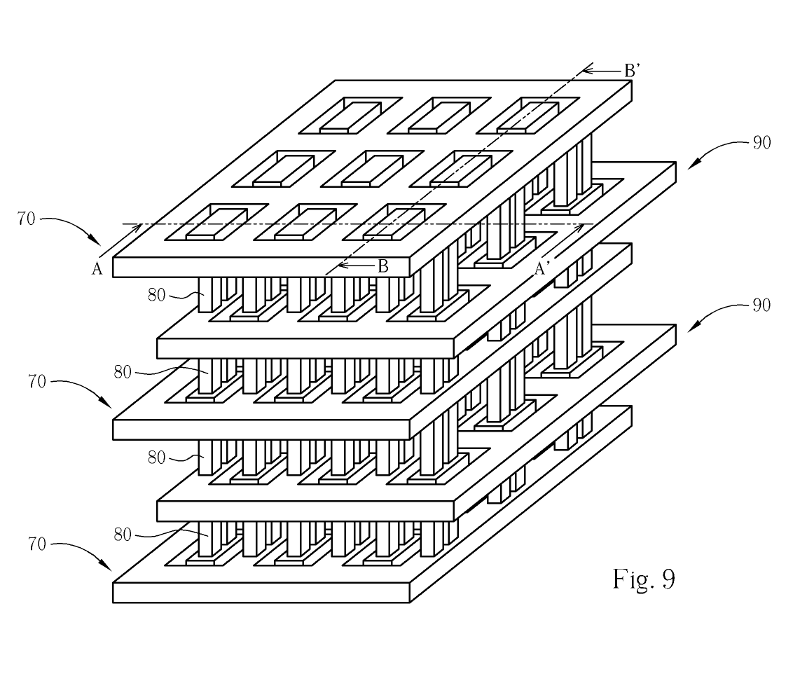

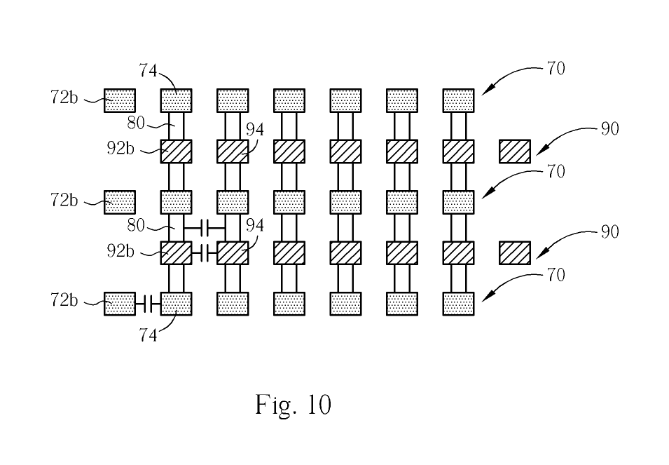

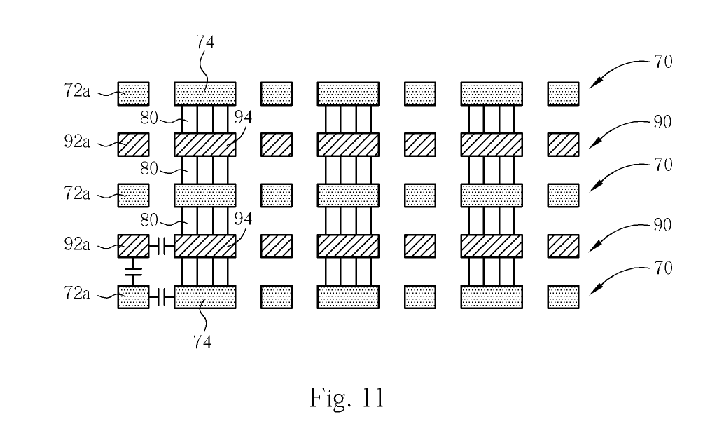

Please refer to FIGS. 9-11. FIG. 9 is a schematic diagram of a three-dimensional capacitor structure of a second embodiment according to the present invention. FIG. 10 is a cross-sectional diagram of the three-dimensional capacitor structure in FIG. 9 along a section line A-A′. FIG. 11 is a cross-sectional diagram of the three-dimensional capacitor structure in FIG. 9 along a section line B-B′. The embodiment follows the above-mentioned example of the three-dimensional capacitor structure, which has five conductive layers and the four plug layers.

As FIG. 9 shows, the three-dimensional capacitor structure comprises five conductive layers from top to bottom, and each conductive layer is connected to the rest of the conductive layers by a plurality of plugs. As FIG. 9 shows, the three-dimensional capacitor structure of the present invention is a stack of a plurality of odd conductive layers 70 interspersed between a plurality of even conductive layers 90, the odd conductive layers 70 being offset from the even conductive layers 90, but having a same layout.

As FIGS. 10 and 11 show, anywhere that one of the odd conductive layers 70 is adjacent to one of the even conductive layers 90, where the odd conductive layer 70 is connects to a different voltage than the even conductive layer 90, a capacitive effect occurs in the three-dimensional capacitor structure. The total electrical capacitance is the sum of the horizontal electrical capacitances along the horizontal direction and the vertical electrical capacitances along the vertical direction. The horizontal electrical capacitance is the sum of the capacitances between the conductive strips 72a, 72b of the first closed conductive frame 72 and the first conductive island 74, the capacitances between the conductive strips 92a, 92b of the second closed conductive frame 92 and the second conductive island 94, and the capacitances between plugs 80. The vertical electrical capacitance is the sum of the capacitances between the conductive strip 72a of the first closed conductive frame 72 and the conductive strip 92a of the second closed conductive frame 92.

Please note that, in the above-mentioned embodiment, the first closed conductive frame 72 and the second closed conductive frame 74 are rectangles, but the shape is not limited to rectangles. The shape of the frame could be another shape, such as a parallelogram. Further, two plugs 80 are used to connect electrically the conductive strip 72a and the second conductive island 94, and to connect electrically the conductive strip 92a and the first conductive island 74. The present invention is not limited to this configuration. The number of the plugs 80 could be changed. Furthermore, the material of the first conductive layer 70 and the second conductive layer 90 could be metal, poly-silicon or semiconductor, depending on required electrical performance. Finally, a dielectric layer of the capacitor (not shown) is disposed between the first conductive layer 70, the plug layer, and the second conductive layer 90. The dielectric layer could be adjusted through material, thickness, and width, to name a few.

In conclusion, the three-dimensional capacitor structure of the present invention has low resistance, high matching, high capacitance, and increases the integration of integrated circuits.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A three-dimensional capacitor structure comprising:
a first conductive layer comprising:
a plurality of first closed conductive frames in a matrix; and
a plurality of first conductive islands disposed individually in the first closed conductive frames, the first conductive islands are not connected electrically with the first closed conductive frames;
a second conductive layer disposed on the first conductive layer, the second conductive layer comprising:
a plurality of second closed conductive frames in a matrix; and
a plurality of second conductive islands disposed individually in the second closed conductive frames, the second conductive islands are not connected electrically with the second closed conductive frames, the second closed conductive frames of the second conductive layer correspond to the first conductive islands of the first conductive layer, and the second conductive islands of the second conductive layer correspond to the first closed conductive frame of the first conductive layer; and
a plug layer disposed between the first conductive layer and the second conductive layer, the plug layer comprising a plurality of plugs, each plug being between each first conductive island and each second closed conductive frame, and between each first closed conductive frame and each second conductive island.

2. The three-dimensional capacitor structure of claim 1, wherein each first closed conductive frame comprises two conductive strips along a first direction, and two conductive strips along a second direction, and each conductive strip of the first closed conductive frame along the first direction corresponds to the second conductive island.

3. The three-dimensional capacitor structure of claim 1, wherein each second closed conductive frame comprises two conductive strips along a first direction, and two conductive strips along a second direction, and each conductive strip of the second closed conductive frame along the first direction corresponds to the first conductive island.

4. The three-dimensional capacitor structure of claim 1 further comprising a horizontal electrical capacitance, wherein the horizontal electrical capacitance is a sum of a capacitance between the first closed conductive frame and the first conductive island, a capacitance between the second closed conductive frame and the second conductive island, and the capacitance between the plugs.

5. The three-dimensional capacitor structure of claim 1 further comprising a vertical electrical capacitance, wherein the vertical electrical capacitance is a sum of a capacitance between the first closed conductive frame and the second closed conductive frame.
